(19) United States
(12) Patent Application Publication
(10) Pub. No.: US 2010/0267225 A1
(43) Pub. Date: Oct. 21, 2010

(54) Method of manufacturing semiconductor device

(76) Inventors: Hyo-san Lee, Suwon-si (KR); Bo-un Yoon, Seoul (KR); Kun-tack Lee, Suwon-si (KR); Dae-hyuk Kang, Hwaseong-si (KR); Jeong-nam Han, Seoul (KR); Jung-jae Myung, Iksan-si (KR); Hyung-pyo Hong, Iksan-si (KR); Hun-pyo Hong, Iksan-si (KR)

Correspondence Address: LEE & MORSE, P.C., 3141 FAIRVIEW PARK DRIVE, SUITE 500, FALLS CHURCH, VA, 22042, US

(21) Appl. No.: 12/385,658

(22) Filed: Apr. 15, 2009

(51) Int. Cl. H01L 21/265; H01L 21/306

(52) U.S. Cl. 438/514; 438/754; 257/E21.219; 257/E21.334

(57) ABSTRACT

A method of manufacturing a semiconductor device, the method including forming a photoresist film on a substrate, and removing the photoresist film from the substrate using a composition that includes a sulfuric acid solution, a hydrogen peroxide solution, and a corrosion inhibitor.

### BACKGROUND

1. Technical Field

Embodiments relate to a method of manufacturing a semiconductor device.

2. Description of the Related Art

As semiconductor devices have become highly integrated, a design rule for a cell array region of a memory device, e.g., a Dynamic Random Access Memory (DRAM) and a flash memory, has been reduced.

When manufacturing a semiconductor device, photoresist may be used as a material for an etching mask or an ion implantation mask for an etching process or an ion implantation process, respectively. In order to remove the photoresist remaining after etching or ion implantation, and other remaining polymer residuals, ashing and stripping using an organic cleaning solution have been used. However, when a portion of a metal film or a metal nitride film in, e.g., a metal gate or a metal bit line, is exposed and ashing is performed to remove the photoresist and the polymer residuals remaining on the substrate, the exposed films may be damaged due to, e.g., oxidation or corrosion, resulting in a low-quality device. In particular, a photoresist mask, used during ion implantation for forming a source/drain region on a substrate, may be hardened due to a high dose of ions during ion implantation, and the hardened photoresist mask may not be completely removed through conventional ashing and stripping.

### SUMMARY

Embodiments are therefore directed to a method of manufacturing a semiconductor device, which substantially overcome the problems due to the limitations and disadvantages of the related art.

It is therefore a feature of an embodiment to provide a method of manufacturing a semiconductor device that removes a photoresist and polymer residuals remaining on a substrate without damaging a metal or metal film when the metal or metal film is exposed on the substrate.

At least one of the above and other features and advantages may be realized by providing a method of manufacturing a semiconductor device, the method including forming a photoresist film on a substrate, and removing the photoresist film from the substrate using a composition that includes a sulfuric acid solution, a hydrogen peroxide solution, and a corrosion inhibitor.

The substrate may include a metal containing film, and the metal containing film may be exposed to the composition during the removing of the photoresist film.

The metal containing film may include at least one of tungsten, tungsten nitride, tungsten silicide, tantalum nitride, titanium nitride, tantalum, molybdenum, copper, gold, silver, ruthenium, platinum, rhodium, iridium, osmium, palladium, platinum oxide, rhodium oxide, ruthenium oxide, iridium oxide, osmium oxide, palladium oxide, calcium ruthenium oxide, strontium ruthenium oxide, barium ruthenium oxide, barium strontium ruthenium oxide, calcium iridium oxide, strontium iridium oxide, barium iridium oxide, (lanthanum, strontium) cobalt oxide, molybdenum silicide, tantalum silicide, zirconium silicon nitride, zirconium aluminum nitride, molybdenum silicon nitride, molybdenum aluminum nitride, tantalum silicon nitride, or tantalum aluminum nitride.

The method may further include etching the metal containing film using the photoresist film as an etching mask, prior to removing of the photoresist film.

The sulfuric acid solution may be a 96% sulfuric acid solution, the hydrogen peroxide solution may be a 30% hydrogen peroxide solution, and the 30% hydrogen peroxide solution may be included in an amount of about 3 to 10 weight % based on the total weight of the composition.

The corrosion inhibitor may include an ammonium salt compound.

The ammonium salt compound may include at least one of ammonium thiosulfate, ammonium sulfate, ammonium persulfate, ammonium phosphate, ammonium sulfate, ammonium nitrate, ammonium borate, ammonium citrate, ammonium oxalate, ammonium formate, and ammonium carbonate.

The composition may further include a strip enhancer.

The strip enhancer may include a fluoric compound.

The fluoric compound may include at least one of ammonium fluoride, ammonium hydrofluoride, ammonium borofluoride, fluoroboric acid, and hydrogen fluoride.

The method may further include implanting impurity ions in the substrate having the photoresist film thereon by using the photoresist film as an ion implantation mask, prior to removing the photoresist film.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1A through 1C illustrate cross-sectional diagrams of stages in a method of manufacturing a semiconductor device according to an embodiment;

FIGS. 2A through 2C illustrate cross-sectional diagrams of stages in a method of manufacturing a semiconductor device according to another embodiment;

FIG. 3 illustrates a graph showing evaluation results for an etching amount of a metal film with respect to hydrogen peroxide solution content during stripping of photoresist;

FIG. 4 illustrates a graph showing evaluation results for an etching amount of a metal film with respect to additives of compositions for stripping photoresist;

FIG. 5 illustrates a graph showing results for an etching amount of a metal film with respect to temperature and hydrogen peroxide solution content of compositions for stripping photoresist;

FIG. 6 illustrates a graph showing results for an etching amount of various films with respect to hydrogen peroxide solution content of compositions for stripping photoresist;

FIG. 7 illustrates Table 1, showing components and amounts for Examples 1 to 5;

FIG. 8 illustrates Table 2, showing components and amounts for Comparative Examples 1 to 3; and

FIG. 9 illustrates Table 3, showing stripping capability and corrosion test results for compositions prepared according to Examples 1 to 5 and Comparative Examples 1 to 3.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an n^{th} member, where n is greater than 3, whereas the expression “at least one selected from the group consisting of A, B, and C” does not.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B, and C together, whereas the expression “either A, B, or C” means one of A alone, B alone, and C alone, and does not mean any of both A and B together; both A and C together; both B and C together; and all three of A, B, and C together.

As used herein, the terms “a” and “an” are open terms that may be used in conjunction with singular items or with plural items. For example, the term “a metal” may represent a single compound, e.g., tungsten, or multiple compounds in combination, e.g., tungsten mixed with titanium.

Embodiments provide a composition for stripping photoresist which may be used to remove photoresist or polymer residuals remaining on a substrate. In a method of manufacturing a semiconductor device, a predetermined process for manufacturing a semiconductor device on the substrate, e.g., etching or ion implantation, may be performed; and then the composition for stripping photoresist may be used to remove the photoresist and/or the polymer residuals remaining on the substrate. The photoresist may be stripped without ashing the photoresist.

The composition for stripping photoresist may include a mixture of a sulfuric acid solution and a hydrogen peroxide solution. In the composition for stripping photoresist, the sulfuric acid solution may be a 96% sulfuric acid solution, and the hydrogen peroxide solution may be a 30% hydrogen peroxide solution. Here, the concentration unit of the sulfuric acid solution and the hydrogen peroxide solution is weight %. Hereinafter, when the symbol “%” is used, the symbol denotes weight %. In the composition for stripping photoresist, the 30% hydrogen peroxide solution may be included in an amount of about 3 to about 10 weight % based on the total weight of the composition.

In the composition for stripping photoresist, the weight ratio of pure sulfuric acid and pure hydrogen peroxide may be about 1:1 to about 10,000:1. Maintaining the weight ratio of sulfuric acid and hydrogen peroxide at about 1:1 or greater, i.e., when the content of sulfuric acid is greater than the content of hydrogen peroxide in the composition, may help ensure that a metal film, e.g., tungsten, a polysilicon film, an oxide film, and/or an insulation film, exposed to the composition is not corroded. Maintaining the weight ratio of sulfuric acid and hydrogen peroxide at about 10,000:1 or less, i.e., when the content of sulfuric acid is less than about 10,000 parts based on 1 part of hydrogen peroxide, may help ensure that the effect of stripping photoresist hardened after ion implantation or polymer residuals is not reduced.

In the composition for stripping photoresist according to an embodiment, the mixture of the sulfuric acid solution and the hydrogen peroxide solution may be included in an amount of about 85 to about 100 weight % based on the total weight of the composition. Maintaining the content of the mixture of the sulfuric acid solution and the hydrogen peroxide solution at about 85% weight or greater may help ensure that the effect of stripping the hardened photoresist or polymer residuals is not reduced.

The composition for stripping photoresist according to an embodiment may further include a corrosion inhibitor. The corrosion inhibitor may include, e.g., an ammonium salt compound. The ammonium salt compound may form Caro's acid (peroxymonosulfuric acid, H₂SO₅) through an interactive ionic reaction with sulfuric acid, and may prevent corrosion of a metal, e.g., tungsten. The ammonium salt compound may include, e.g., ammonium thiosulfate, ammonium sulfate, ammonium persulfate, ammonium phosphate, ammonium sulfate, ammonium nitrate, ammonium borate, ammonium citrate, ammonium oxalate, ammonium formate, and ammonium carbonate. The ammonium salt compound used in an embodiment is not limited to the examples above. The ammonium salt compound may be included in the composition for stripping photoresist in an amount of about 0.01 to about 15 weight % based on the total weight of the composition. In the composition for stripping photoresist, the water content in the sulfuric acid solution and the hydrogen peroxide solution may improve the activity of Caro's acid formed by sulfuric acid and hydrogen peroxide.

The composition for stripping photoresist according to an embodiment may further include a strip enhancer. The strip enhancer may include, e.g., a fluoric compound. The fluoric compound may etch and remove residuals, which may not be removed by the mixture of the sulfuric acid solution and the hydrogen peroxide solution alone. The fluoric compound may include, e.g., ammonium fluoride, ammonium hydrofluoride, ammonium borofluoride, fluoroboric acid, and hydrogen fluoride. The fluoric compound is not limited to the examples above. The strip enhancer may be included in the composition for stripping photoresist in an amount of about 0.001 to about 5 weight % based on the total weight of the composition.

The composition for stripping photoresist according to an embodiment may efficiently strip photoresist hardened during manufacture of a semiconductor device, and in particular, after ion implantation or ashing at a high temperature. The composition for stripping photoresist according to an embodiment may also strip polymer residuals.

The composition for stripping photoresist according to an embodiment may be manufactured by, e.g., mixing the compounds above in a predetermined mixing ratio. A method of mixing is not particularly restricted and various well-known methods may be used.

In addition, an embodiment provides a method of stripping using the composition for stripping photoresist. The method of stripping may include contacting a substrate including photoresist with the composition for stripping photoresist. For example, dipping, spraying, and/or a mixed method may be used. In the stripping process using the composition for stripping photoresist, a temperature of the composition may be about 30 to about 150° C., and preferably, about 50 to 100° C. The time of the stripping process may be about 30 seconds to about 40 minutes, and preferably, about 1 to about 20 minutes. However, the temperature and the time are not particularly restricted and suitable conditions may be selected by one of skill in the art.

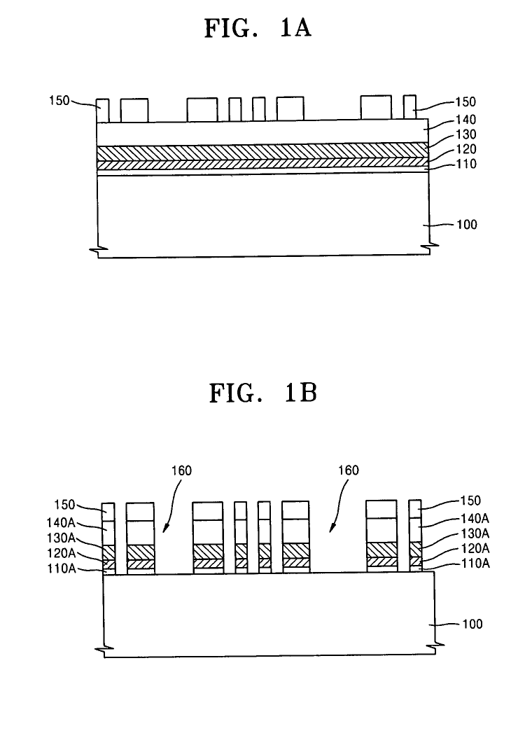

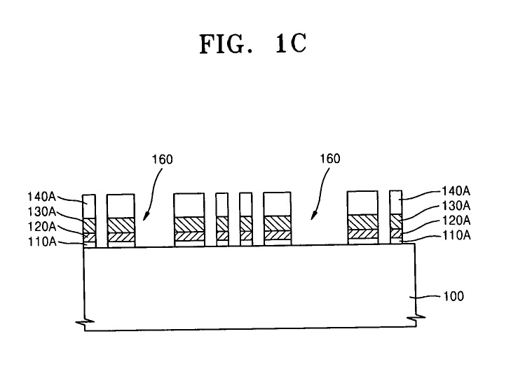

FIGS. 1A through 1C illustrate cross-sectional diagrams showing a method of manufacturing a semiconductor device according to an embodiment. In FIGS. 1A through 1C, a series of processes for forming a gate electrode on a semiconductor substrate 100 are illustrated. In the present embodiment, a process for forming a gate electrode of a flash memory device is described as an example.

Referring to FIG. 1A, an insulating layer 110 for forming a gate insulation film, a first conductive layer 120, and a second conductive layer 130 may be sequentially formed on the semiconductor substrate 100. A hard mask layer 140 may be formed on the second conductive layer 130 and a photoresist pattern 150 may be formed on the hard mask layer 140.

The insulating layer 110 may have a stacked structure, in which, e.g., a silicon oxide film, a silicon nitride film, and an Al₂O₃ film may be sequentially stacked, but the embodiments are not limited thereto. The first conductive layer 120 may be formed of a metal nitride film, e.g., a TaN film. The second conductive layer 130 may be formed of, e.g., a metal film or a combination of a metal nitride film and a metal film. For example, the second conductive layer 130 may have a stacked structure in which, e.g., a WN film and a W film are sequentially stacked. The hard mask layer 140 may be formed of, e.g., a silicon oxide film, a silicon nitride film, or a combination thereof.

Referring to FIG. 1B, the photoresist pattern 150 may be used as an etching mask to etch the hard mask layer 140 and thus, a hard mask pattern 140A may be formed. Then, the photoresist pattern 150 and the hard mask pattern 140A may be used as an etching mask to sequentially etch the second conductive layer 130, the first conductive layer 120, and the insulating layer 110 and thus, a plurality of gate patterns 160 including a gate insulation film 110A, first conductive layer pattern 120A, and a second conductive layer pattern 130A may be formed.

After the etching process for forming the gate patterns 160, the photoresist pattern 150 may remain on the hard mask pattern 140A and polymers, e.g., etching residuals, may be attached on the side walls of the gate patterns 160.

Referring to FIG. 1C, the composition for stripping photoresist according to an embodiment may be used to remove the photoresist pattern 150 remaining on the hard mask pattern 140A, and the polymer residuals attached on the side walls of the gate patterns 160. In order to remove the photoresist pattern 150 and the polymer residuals, the semiconductor substrate 100 having the photoresist pattern 150 thereon may be dipped in the composition for stripping photoresist, or the composition for stripping photoresist may be sprayed on the semiconductor substrate 100 having the photoresist pattern 150 thereon.

During removal of the photoresist pattern 150 and the polymer residuals using the composition for stripping photoresist according to an embodiment, although a metal film or a metal nitride film forming the gate patterns 160 may be exposed, damage to the films due to the composition for stripping photoresist may be minimized, and the composition for stripping photoresist may not seriously affect the films.

In the present embodiment described with reference to FIGS. 1A through 1C, while the metal film or the metal nitride film forming the gate patterns 160 on the semiconductor substrate 100 may be exposed, the composition for stripping photoresist according to an embodiment may be used to remove the photoresist pattern 150 and the polymer residuals. However, the present embodiment is not limited thereto. Also, a removal process for the photoresist pattern 150 and the polymer residuals using the composition for stripping photoresist according to an embodiment may be performed while various metal containing films, e.g., various kinds of metal films, metal nitride films, and alloy films, may be exposed. According to an embodiment, although various metal containing films may be exposed, damage to the exposed metal containing films may be minimized and a desired stripping process may be efficiently performed. For example, while various metals including, e.g., tungsten, W, tungsten nitride, WN, tungsten silicide, WSi, tantalum nitride, TaN, titanium nitride, TiN, tantalum, Ta, molybdenum, Mo, copper, Cu, gold, Au, silver, Ag, ruthenium, Ru, platinum, Pt, rhodium, Rh, iridium, Ir, osmium, Os, palladium, Pd, platinum oxide, PtOₓ, rhodium oxide, RhOₓ, ruthenium oxide, RuOₓ, iridium oxide, IrOₓ, osmium oxide, OsOₓ, palladium oxide, PdOₓ, calcium ruthenium oxide, CaRuO₃, strontium ruthenium oxide, SrRuO₃, barium ruthenium oxide, BaRuO₃, barium strontium ruthenium oxide, BaSrRuO₃, calcium iridium oxide, CaIrO₃, strontium iridium oxide, SrIrO₃, barium iridium oxide, BaIrO, (lanthanum, strontium) cobalt oxide, (La,Sr)CoO₃, molybdenum silicide, MoSiₓ, tantalum silicide, TaSiₓ, zirconium silicon nitride, ZrSiN, zirconium aluminum nitride, ZrAlN, molybdenum silicon nitride, MoSiN, molybdenum aluminum nitride, MoAlN, tantalum silicon nitride, TaSiN, and/or tantalum aluminum nitride, TaAlN, or a combination thereof, or metal containing films may be exposed on a substrate having remaining photoresist or polymer residuals, a stripping process for the photoresist or the polymer residuals may be performed.

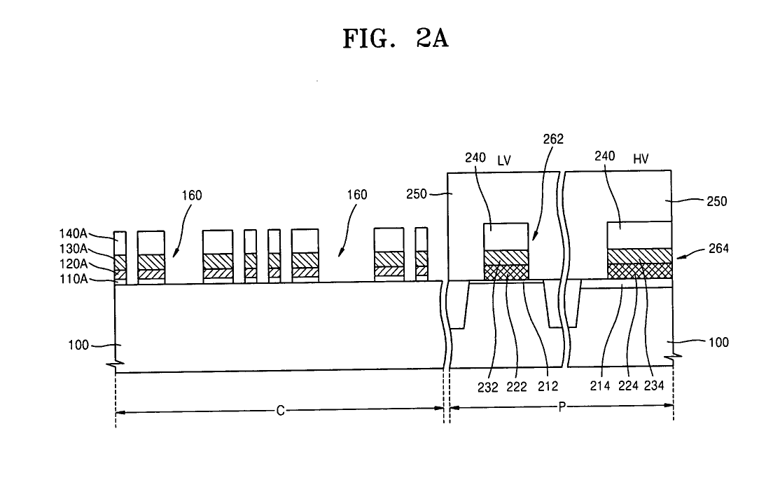

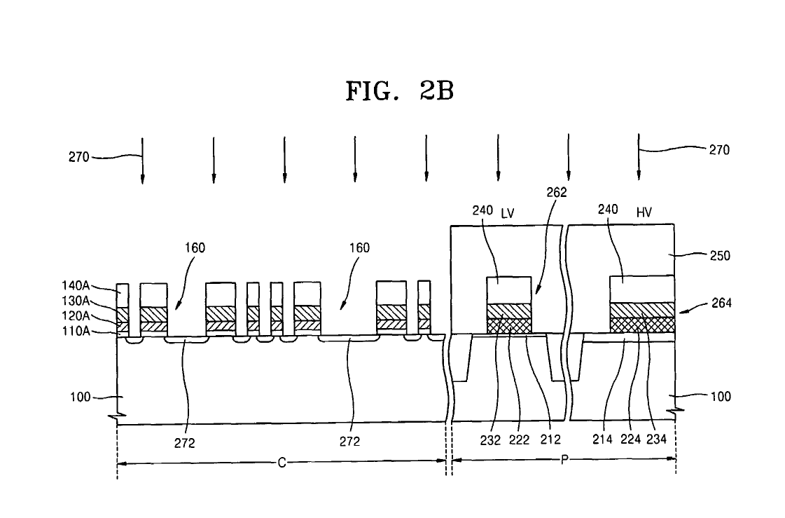

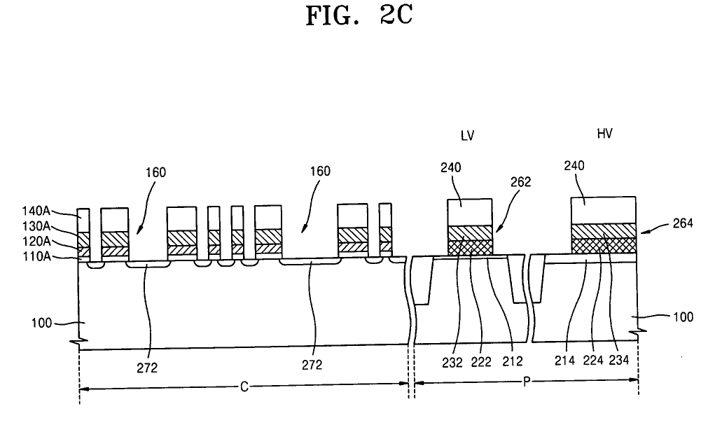

FIGS. 2A through 2C illustrate cross-sectional diagrams showing a method of manufacturing a semiconductor device according to another embodiment. In FIGS. 2A through 2C, a series of processes for ion implantation on the semiconductor substrate 100, on which a gate electrode may be formed, are illustrated. In the present embodiment, the semiconductor substrate 100 may include a cell array region C and a peripheral circuit region P. The peripheral circuit region P may be divided into a low voltage circuit region LV and a high voltage circuit region HV. In FIGS. 2A through 2C, like reference numerals as in the previous embodiment denote like elements.

Referring to FIG. 2A, a plurality of gate patterns 160, 262, and 264 may be formed on the semiconductor substrate 100 using the method described with reference to FIGS. 1A through 1C. The gate patterns 160 may be formed on the cell array region C of the semiconductor substrate 100, the gate pattern 262 may be formed on the low voltage circuit region LV, and the gate pattern 264 may be formed on the high voltage circuit region HV.

The gate pattern 262 formed in the low voltage circuit region LV may include, e.g., a gate insulation film 212 for LV having a smaller thickness than a gate insulation film 214 in the high voltage circuit region HV, and gate electrode layers 222 and 232 formed on the gate insulation film 212 for LV. The gate electrode layers 222 and 232 may include, e.g., a polysilicon layer 222 and a W/WN structural layer 232, in which a WN film and a W film may be sequentially stacked.

The gate pattern 264 formed in the high voltage circuit region HV may include, e.g., the gate insulation film 214 for HV having a larger thickness than the gate insulation film 212 for LV, and gate electrode layers 224 and 234. The gate electrode layers 224 and 234 may include, e.g., a polysilicon layer 224 and a W/WN structural layer 234, in which a WN film and a W film may be sequentially stacked.

The gate patterns 262 and 264 may be covered by a hard mask pattern 240. The hard mask pattern 240 may include, e.g., a material for forming the hard mask pattern 140A included in the gate patterns 160 in the cell array region C.

A photoresist pattern 250 may be formed on the resultant product, in which the plurality of gate patterns 160, 262, and 264 are formed, to cover the peripheral circuit region P. The photoresist pattern 250 may be formed to not cover the cell array region C and thus, the semiconductor substrate 100 may be exposed in the cell array region C.

Referring to FIG. 2B, the photoresist pattern 250 may be used as an ion implantation mask, and impurity ions 270 may be implanted to form a plurality of ion implantation regions 272 on the cell array region C. The plurality of ion implantation regions 272 may form a part of a source/drain in a lightly doped drain (LDD) structure in the cell array region C. While the ion implantation process is performed, the photoresist pattern 250 may be hardened or deteriorated.

Referring to FIG. 2C, the composition for stripping photoresist according to an embodiment may be used to remove the photoresist pattern 250. Although the photoresist pattern 250 may be hardened or deteriorated after the ion implantation process, the composition for stripping photoresist according to an embodiment may be used to efficiently remove the photoresist pattern 250.

When removing of the photoresist pattern 250 using the composition for stripping photoresist according to an embodiment, although a metal film or a metal nitride film forming the gate patterns 160, 262, and 264 may be exposed, damage to the films due to the composition for stripping photoresist may be minimized, and the composition for stripping photoresist may not seriously affect the films.

### EVALUATION EXAMPLE 1

Stripping Capability and Corrosion Evaluation

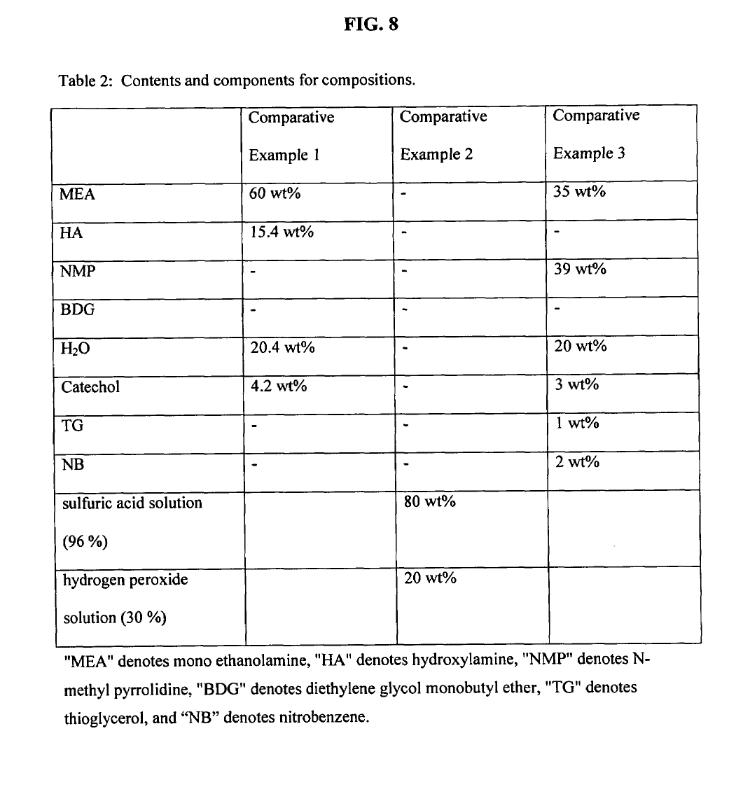

The composition for stripping photoresist according to an embodiment may be manufactured to have various contents as illustrated in Examples 1 through 5 in Table 1 of FIG. 7. In addition, compositions for comparison were manufactured to have various contents as illustrated in Comparative Examples 1 through 3 in Table 2 of FIG. 8.

(1) Evaluation on Stripping Capability

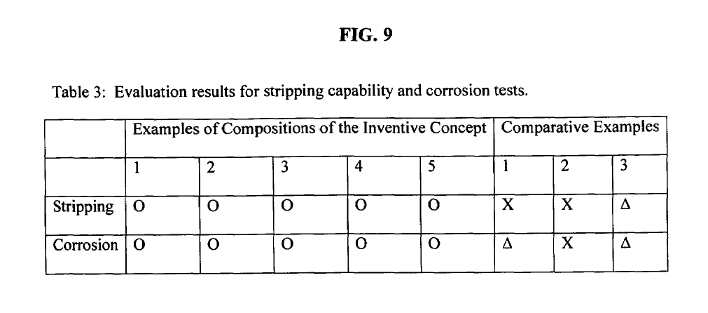

After ion implantation with high doses of ions, samples in which hardened photoresist and/or photoresist changed to polymer were attached to the surface of the polysilicon layer were respectively dipped in the compositions at a temperature of 65° C. as in Examples 1 through 5 and in Comparative Examples 1 through 3, for 10 minutes, and were then taken out of the stripping solution. Then, the samples were rinsed with deionized water for 1 minute and were dried using nitrogen gas. Next, the capability to remove a photoresist was evaluated using a scanning electron microscope and the results are shown in Table 3 of FIG. 9.

In Table 3, the standards for evaluating the capability to remove photoresist are as follows.

O: when a hardened photoresist and a photoresist changed to polymer on the surface of the polysilicon layer was completely removed.

Δ: when a hardened photoresist on the surface of the polysilicon layer was completely removed and 70% or more of a photoresist changed to polymer was removed

X: when a hardened photoresist on the surface of the polysilicon layer was not removed or 50% or less of a photoresist changed to polymer was removed.

(2) Corrosion Evaluation

Samples in which a polysilicon layer and a tungsten layer were coated on a bare Si substrate were respectively dipped in the compositions at a temperature of 65° C., as in Examples 1 through 5 and in Comparative Examples 1 through 3, for 10 minutes, and were then taken out of the stripping solution. Then, the samples were rinsed with deionized water for 1 minute and dried using nitrogen gas. Next, corrosion was evaluated using a thickness gauge (non-contact thickness gauge, Filmetrix) and the results are shown in Table 3.

In Table 3, the standards for evaluating corrosion are as follows

O: when etching amounts per minute of the polysilicon layer and the tungsten layer were respectively less than 0.5 Å and 0.2 Å.

Δ: when etching amounts per minute of the polysilicon layer and the tungsten layer were respectively 0.5-1 Å and 0.2-0.5 Å.

X: when etching amounts per minute of the polysilicon layer and the tungsten layer were respectively greater than 1 Å and 0.5 Å or when corrosion could be identified using an optical microscope.

### EVALUATION EXAMPLE 2

Evaluation of Etching Amount of Metal Film with Respect Hydrogen Peroxide Solution Content

In order to evaluate the etching amount of the metal film with respect to the hydrogen peroxide solution content in the composition for stripping photoresist according to an embodiment, compositions respectively including 1 weight %, 2 weight %, 3 weight %, 4 weight %, 8 weight %, 12 weight %, and 20 weight % of 30% hydrogen peroxide solutions based on the total weight of the compositions were prepared as the compositions for stripping photoresist. The compositions also included 96% sulfuric acid solution. Tungsten film was etched using the compositions.

The temperature of each composition during etching was 60° C., and the etching time was 5 minutes.

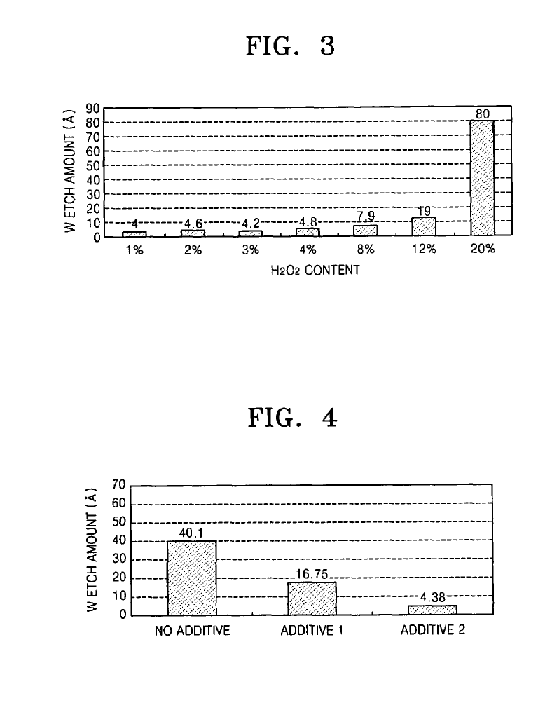

FIG. 3 illustrates a graph showing evaluation results for an etching amount of the tungsten film with respect to the hydrogen peroxide solution contents during stripping of photoresist. In FIG. 3, as the hydrogen peroxide solution content increases, the etching amount of the tungsten film also increases.

### EVALUATION EXAMPLE 3

Evaluation of Etching Amount of Metal film with Respect to Additives of Composition for Stripping Photoresist

In order to evaluate the etching amount of a metal film with respect to the additive selection in the composition for stripping photoresist according to an embodiment, the composition for stripping photoresist (No Additive) including 96% sulfuric acid solution and 30% hydrogen peroxide solution, the composition for stripping photoresist (Additive 1) further containing 1.5 weight % of ammonium phosphate based on the total weight of the composition, and the composition for stripping photoresist (Additive 2) further containing 1.5 weight % of ammonium sulfate based on the total weight of the composition were respectively prepared. Tungsten film was etched using the compositions. The 30% hydrogen peroxide solution content in each composition was 3 weight % based on the total weight of the composition. A temperature of each composition during etching of the tungsten film was 65° C., and the etching time was 20 minutes.

FIG. 4 illustrates a graph showing the evaluation results for an etching amount of the tungsten film with respect to additives of compositions for stripping photoresist. In FIG. 4, the etching amount of the tungsten was significantly reduced in the compositions including ammonium phosphate or ammonium sulfate. Accordingly, in the compositions including ammonium phosphate or ammonium sulfate, detrimental etching of the exposed metal film may be minimized, and a process margin for improving photoresist stripping capability may be secured.

### EVALUATION EXAMPLE 4

Evaluation of Etching Amount of Metal Film with Respect to Temperature and Hydrogen Peroxide Solution Content

In order to evaluate the etching amount of the metal film with respect to temperature of the composition for stripping photoresist, and the hydrogen peroxide solution content, compositions respectively including 3.0 weight %, 5.0 weight %, and 8.0 weight % of the 30% hydrogen peroxide solution based on the total weight of the composition were prepared as the compositions for stripping photoresist. The composition also included 96% sulfuric acid solution and ammonium sulfate. In the compositions, the content of ammonium sulfate was 1.5 weight % based on the total weight of the composition. The evaluation was performed in a batch tool, and the etching time for the tungsten film was 20 minutes.

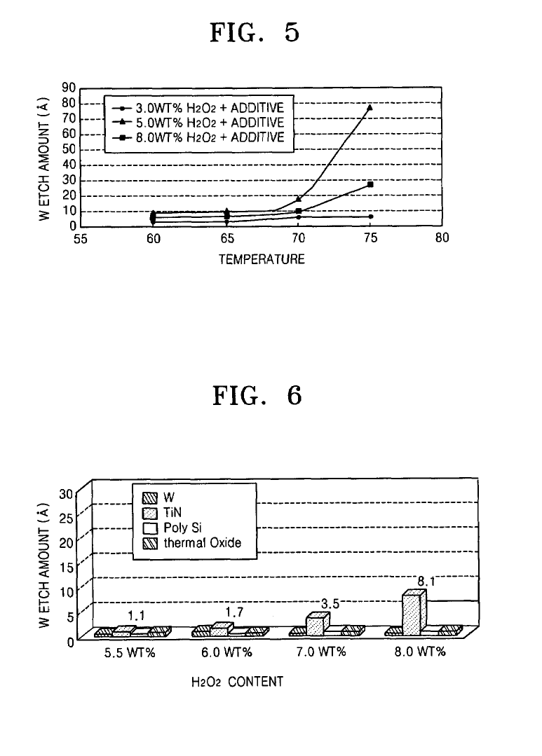

FIG. 5 illustrates a graph showing the results for an etching amount of the tungsten film when the tungsten film was etched using the compositions for stripping photoresist according to an embodiment.

According to the results shown in FIG. 5, in the batch tool, etching of the metal film was minimized at a process temperature of about 60-70° C. in which the compositions for stripping photoresist according to an embodiment were used, so that detrimental effects on the exposed metal film were minimized in the temperature range, and excellent stripping effect may be obtained. In addition, when the hydrogen peroxide solution content was about 5.0 to 6.5 weight % in the compositions, and the time for the stripping process was about 15-20 minutes, detrimental effects on other exposed films were minimized and excellent stripping effect may be obtained.

### EVALUATION EXAMPLE 5

Evaluation of Etching Amount of Various Films with Respect to Hydrogen Peroxide Solution Content in Composition for Stripping Photoresist

In order to evaluate the etching amounts of various films with respect to the hydrogen peroxide solution content in a composition for stripping photoresist according to an embodiment, compositions respectively including 5.5 weight %, 6.0 weight %, 7.0 weight %, and 8.0 weight % of 30% hydrogen peroxide solution based on the total weight of the compositions were prepared as the compositions for stripping photoresist. The compositions also included 96% sulfuric acid solution and ammonium sulfate. In the compositions, the content of ammonium sulfate was 1.5 weight % based on the total weight of the composition. The evaluation was performed in a single tool, the temperature of the compositions during etching of the films was 65° C., and the etching time was 1 minute. For the evaluation, the compositions for stripping photoresist were applied using spin coating on the various films to be etched.

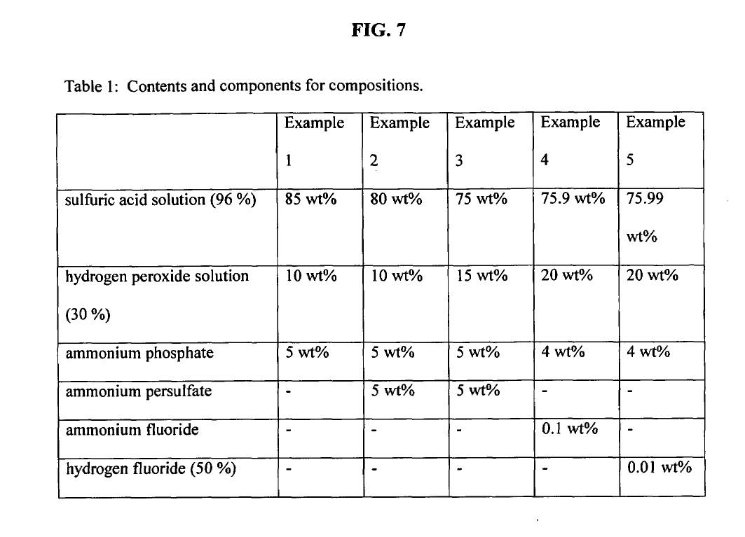

FIG. 6 illustrates a graph showing the evaluation results for etching amounts of the various films when the tungsten film, a TiN film, a polysilicon film, and a thermal oxidation film were etched using the composition for stripping photoresist according to an embodiment.

According to the results shown in FIG. 6, when the hydrogen peroxide solution content was about 5.5 to 7.5 weight % in the compositions during the stripping process, and the time for the stripping process was about 1-2 minutes, a detrimental effect on other exposed films was minimized and an excellent stripping effect was obtained.

### EVALUATION EXAMPLE 6

Evaluation of Defect Occurrence with Respect to Fluoric Compound Content in a Composition for Stripping Photoresist

In order to evaluate an amount of defect occurrence with respect to the fluoric compound content in the composition for stripping photoresist according to an embodiment, compositions including 96% sulfuric acid solution and 30% hydrogen peroxide solution in which the hydrogen peroxide solution contents were respectively 5.5 weight % (composition 1) and 6.0 weight % (composition 2) based on the total weight of the compositions, were prepared. Also, a composition for stripping photoresist (composition 3) further including ammonium fluoride in a mixture of 96% sulfuric acid solution and 30% hydrogen peroxide solution was prepared. In the composition 3, the hydrogen peroxide solution content was 6.0 weight % based on the total weight of the composition, and the content of ammonium fluoride was 500 ppm based on the total weight of the composition. The compositions 1, 2, and 3 were used to clean the surface of silicon substrates, and residues and defects remaining on the surface of the silicon substrates were evaluated based on a number of particles. The temperature of each composition was 65° C., and the etching time was 20 minutes (15 minutes for the composition 3). The permitted standard for the number of particles was set to 90 nm, and the number of particles having a diameter greater than the standard size was measured. As a result, 100 to 172 particles were measured in the compositions 1, 2, and 3. These numbers are acceptable in a current semiconductor device manufacturing process. In particular, the composition including ammonium fluoride as in the composition 3 was effective in terms of removing defects, compared with the composition having no ammonium fluoride, and thus may have the advantage of securing a process margin.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of manufacturing a semiconductor device, the method comprising:
forming a photoresist film on a substrate; and
removing the photoresist film from the substrate using a composition that includes:
a sulfuric acid solution,
a hydrogen peroxide solution, and
a corrosion inhibitor.

2. The method as claimed in claim 1, wherein the substrate includes a metal containing film, and the metal containing film is exposed to the composition during the removing of the photoresist film.

3. The method as claimed in claim 2, wherein the metal containing film includes at least one of tungsten, tungsten nitride, tungsten silicide, tantalum nitride, titanium nitride, tantalum, molybdenum, copper, gold, silver, ruthenium, platinum, rhodium, iridium, osmium, palladium, platinum oxide, rhodium oxide, ruthenium oxide, iridium oxide, osmium oxide, palladium oxide, calcium ruthenium oxide, strontium ruthenium oxide, barium ruthenium oxide, barium strontium ruthenium oxide, calcium iridium oxide, strontium iridium oxide, barium iridium oxide, (lanthanum, strontium) cobalt oxide, molybdenum silicide, tantalum silicide, zirconium silicon nitride, zirconium aluminum nitride, molybdenum silicon nitride, molybdenum aluminum nitride, tantalum silicon nitride, or tantalum aluminum nitride.

4. The method as claimed in claim 2, further comprising etching the metal containing film using the photoresist film as an etching mask, prior to removing of the photoresist film.

5. The method as claimed in claim 1, wherein the sulfuric acid solution is a 96% sulfuric acid solution, the hydrogen peroxide solution is a 30% hydrogen peroxide solution, and the 30% hydrogen peroxide solution is included in an amount of about 3 to 10 weight % based on the total weight of the composition.

6. The method as claimed in claim 1, wherein the corrosion inhibitor includes an ammonium salt compound.

7. The method as claimed in claim 6, wherein the ammonium salt compound includes at least one of ammonium thiosulfate, ammonium sulfate, ammonium persulfate, ammonium phosphate, ammonium sulfate, ammonium nitrate, ammonium borate, ammonium citrate, ammonium oxalate, ammonium formate, and ammonium carbonate.

8. The method as claimed in claim 1, wherein the composition further includes a strip enhancer.

9. The method as claimed in claim 8, wherein the strip enhancer includes a fluoric compound.

10. The method as claimed in claim 9, wherein the fluoric compound includes at least one of ammonium fluoride, ammonium hydrofluoride, ammonium borofluoride, fluoroboric acid, and hydrogen fluoride.

11. The method as claimed in claim 1, further comprising implanting impurity ions in the substrate having the photoresist film thereon by using the photoresist film as an ion implantation mask, prior to removing the photoresist film.
